(19) United States
(12) Patent Application Publication
(10) Pub. No.: US 2019/0293719 A1
(43) Pub. Date: Sep. 26, 2019

(54) SEMICONDUCTOR DEVICE, SEMICONDUCTOR DESIGNING DEVICE, AND SEMICONDUCTOR TEST DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Masahiko SUGIMOTO, Hiratsuka Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 16/129,440

(22) Filed: Sep. 12, 2018

(30) Foreign Application Priority Data
Mar. 22, 2018 (JP) 2018-055266

(51) Int. Cl. G01R 31/3185; G01R 31/3177; G01R 31/3181

(52) U.S. Cl. CPC G01R 31/318552; G01R 31/318536; G06F 11/27; G01R 31/31813; G01R 31/3177

(57) ABSTRACT

A semiconductor device has a circuit block that includes scan chain circuitry for a scan test, and clock gating circuitry that switches supply and non-supply of a clock signal to the scan chain circuitry based on an enable signal. The circuit block includes a bypass path that bypasses the scan chain circuitry, and selection circuitry that selects one of an output signal from the scan chain circuitry and a signal passing through the bypass path based on the enable signal.

### CROSS REFERENCE TO RELATED APPLICATIONS

This application is based upon and claims the benefit of priority from the prior Japanese Patent Application No. 2018-55266, filed on Mar. 22, 2018, the entire contents of which are incorporated herein by reference.

### FIELD

Embodiments of the present invention relate to a semiconductor device, a semiconductor designing device, and a semiconductor test device.

### BACKGROUND

Semiconductor devices are becoming finer and denser year by year. There has been growing the importance of a scan test in which flip-flops in a semiconductor device are linked in chain form to test for operations. The test of a semiconductor device includes a die sorter process test with a probe card in contact with a wafer and a final test that is conducted after chips are cut out of the wafer and packaged. At the die sorter process test, probes in a probe card are concurrently brought into contact with a large number of pads, which limits significantly consumption current. In general, at a scan test, there is a large amount of consumption current in shift operations where test patterns are applied to observe test responses, which would never be generated in normal operations. When the consumption current in the shift operations exceeds the permissible range of a semiconductor test device, an excessive voltage drop occurs to increase the delays of individual elements on the wafer, and this may be detected as a delay failure. As a result, there is a fear of a test error that a normal circuit is judged as defective, which would cause a yield decrease.

Accordingly, to maintain test quality, the shift frequency in a scan test needs to be decreased to suppress increase of the consumption current. However, decreasing the shift frequency in a scan test would lengthen the test time and cause increase in the costs for testing.

### BRIEF DESCRIPTION OF THE DRAWINGS

FIG. 1 is a block diagram illustrating a schematic configuration of a semiconductor device according to an embodiment;

FIG. 2 is a block diagram illustrating a schematic configuration of a semiconductor designing device for designing the semiconductor device illustrated in FIG. 1;

FIG. 3 is a flowchart of processing operations by the semiconductor designing device illustrated in FIG. 2;

FIG. 4A is a diagram illustrating correspondences between the number of test patterns and failure detection rate;

FIG. 4B is a diagram illustrating corresponding relationships between the kinds of circuit blocks and failure detection rate;

FIG. 5 is a block diagram illustrating a schematic configuration of a semiconductor test device that conducts a scan test on the semiconductor device illustrated in FIG. 1; and

FIG. 6 is a diagram illustrating an example in which a computer implements the functions of a semiconductor designing device and a semiconductor test device.

### DETAILED DESCRIPTION

According to one embodiment, a semiconductor device has a circuit block that includes scan chain circuitry for a scan test, and clock gating circuitry that switches supply and non-supply of a clock signal to the scan chain circuitry based on an enable signal. The circuit block includes a bypass path that bypasses the scan chain circuitry, and a selection circuitry that selects one of an output signal from the scan chain circuitry and a signal passing through the bypass path based on the enable signal.

Embodiments will be described below with reference to the drawings. For the ease of understanding and the convenience of illustration, some of components are omitted or described and illustrated in a modified or simplified manner in this specification and the attached drawings. However, the embodiments are to be interpreted including technical matter that can be expected to perform similar functions.

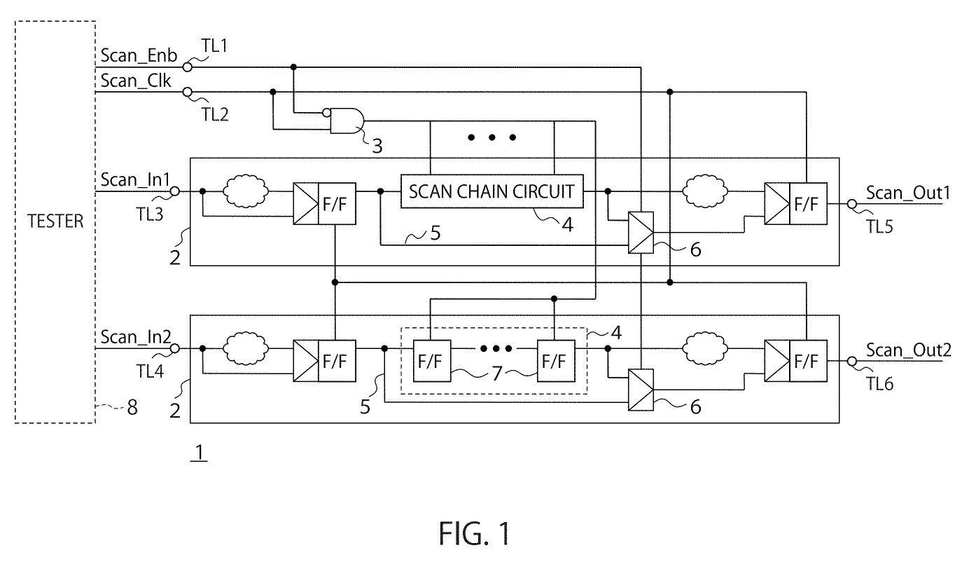

FIG. 1 is a block diagram illustrating a schematic configuration of a semiconductor device 1 according to an embodiment. There is no limitation on the kind and application of the semiconductor device 1 illustrated in FIG. 1. However, the semiconductor device 1 includes at least flip-flops that operate in synchronization with a clock signal Scan_Clk. More specifically, the semiconductor device 1 illustrated in FIG. 1 includes a plurality of circuit blocks 2 and a clock gating circuit (clock gating circuitry) 3 that is connected in common to the plurality of circuit blocks 2. Furthermore, the semiconductor device 1 of FIG. 1 has a terminal TL1 into which an enable signal Scan_Enb is input, a terminal TL2 into which the clock signal Scan_Clk is input, a terminal TL3 into which a test pattern Scan_In1 is input, a terminal TL4 into which a test pattern Scan_In2 is input, a terminal TL5 from which a scan output signal Scan_Out1 is output, and a terminal TL6 from which a scan output signal Scan_Out2 is output. When conducting a scan test, a tester 8 shown by a dotted line in FIG. 1 is connected to the semiconductor device of FIG. 1. More specifically, probes of the tester 8 are contacted to the terminals TL1 to TL6, and then the scan test is conducted.

In this case, each of the circuit blocks 2 has a scan chain circuit (scan chain circuitry) 4 for conducting a scan test, a bypass path 5, and a selection circuit (selection circuitry) 6. The scan chain circuit 4 is typically formed by cascading a plurality of flip-flops 7. Other circuit elements such as a logical gate, an inverter, a resistor, and an inductor may be interposed between these flip-flops 7. The circuit elements such as the flip-flops 7 in the scan chain circuit 4 may operate independently at the time of normal operations, but they form the scan chain circuit 4 at the time of a scan test. The scan chain circuit 4 includes the plurality of flip-flops 7 that operates in synchronization with the clock signal Scan_Clk. Therefore, the clock signal Scan_Clk is input into each of the circuit blocks 2.

The bypass path 5 is a signal path that bypasses the scan chain circuit 4. Circuit elements such as a buffer and a logical gate may be connected in the bypass path 5.

The selection circuit 6 selects an output signal from the scan chain circuit 4 or a signal passing through the bypass path 5, based on the enable signal Scan_Enb for a scan test. For example, the selection circuit 6 selects the output signal from the scan chain circuit 4 when the enable signal Scan_Enb is a first logic (for example, high), and selects the signal passing through the bypass path 5 when the enable signal Scan_Enb is a second logic (for example, low).

The clock gating circuit 3 switches between the supply of the clock signal Scan_Clk and the stop of supply of the clock signal Scan_Clk to the circuit blocks 2 based on the enable signal Scan_Enb. For example, when the enable signal Scan_Enb is the first logic, the clock gating circuit 3 supplies the clock signal Scan_Clk to the circuit blocks 2, and when the enable signal Scan_Enb is the second logic, the clock gating circuit 3 stops the supply of the clock signal Scan_Clk to the circuit blocks 2.

More specifically, the clock gating circuit 3 switches between the supply and non-supply of the clock signal Scan_Clk to the scan chain circuits 4 in the circuit blocks 2 in synchronization with the enable signal Scan_Enb.

There is no particular restriction on the internal configuration of the clock gating circuit 3. In the example of FIG. 1, the clock gating circuit 3 has a logical gate that fixes the output to low when the enable signal Scan_Enb is the second logic (low), and supplies a scan clock from the outside to the scan chain circuits 4 when the enable signal Scan_Enb is the first logic (high). The output signal from the clock gating circuit 3 is supplied to the scan chain circuits 4 in the circuit blocks 2.

Each of the circuit blocks 2 has the test pattern input terminals TL3 and TL4 into which the test pattern Scan_In1 and Scan_In2 are input, respectively. The tester 8 inputs different test patterns into the test pattern input terminals TL3 and TL4 depending on whether the enable signal Scan_Enb is the first logic or the second logic. In the present embodiment, when the enable signal Scan_Enb is the first logic, a first test pattern for conducting a test on the scan chain circuits 4 is supplied to the circuit blocks 2, and when the enable signal Scan_Enb is the second logic, a second test pattern with omission of a test on the scan chain circuits 4 is supplied to the circuit blocks 2.

In the present embodiment, it is not intended that the scan chain circuit 4 in all the circuit blocks 2 in the semiconductor device 1 are connected to the clock gating circuit 3. The clock gating circuit 3 stops the supply of the clock signal Scan_Clk to the circuit block 2 judged as conducting a redundant scan test, out of the plurality of circuit blocks 2 in the semiconductor device 1. Accordingly, the circuit block 2 conducting the redundant scan test no longer conducts an unnecessary redundant scan test, which leads to reduction of the consumption current at the time of a scan test. The reduction of the consumption current suppresses a voltage drop and allows the scan chain circuit 4 to operate at an initially estimated shift frequency. Accordingly, it is possible to achieve a higher-speed scan test and decrease in the cost for testing.

FIG. 1 illustrates the two circuit blocks 2, but there is no particular limit on the number of the circuit blocks 2. The circuit configurations of the circuit blocks 2 can be changed as appropriate and do not need to be the same as far as each of them includes at least the scan chain circuit 4, the bypass path 5, and the selection circuit 6 described above. Further, the circuit blocks 2 can be changed in size and layout as appropriate.

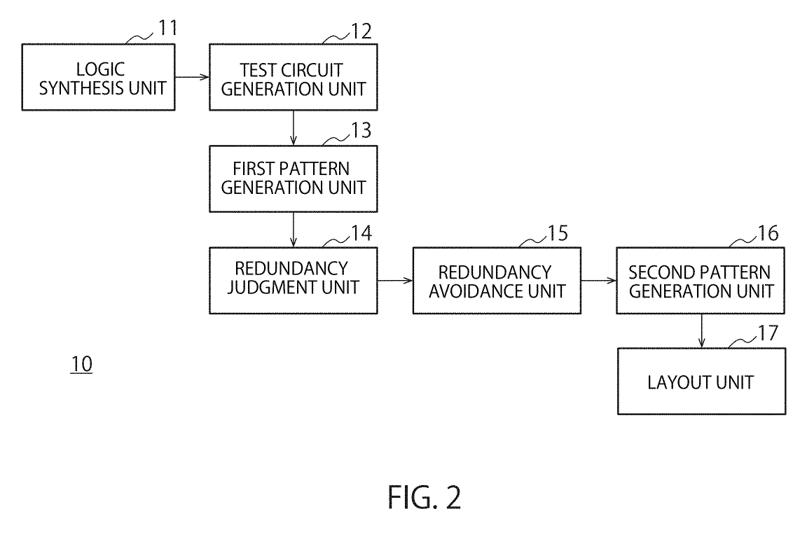

FIG. 2 is a block diagram illustrating a schematic configuration of a semiconductor designing device 10 for designing the semiconductor device 1 illustrated in FIG. 1. The semiconductor designing device 10 illustrated in FIG. 2 includes a logic synthesis unit (logic synthesis circuitry) 11, a test circuit generation unit (test circuit generator) 12, a first pattern generation unit (first pattern generator) 13, a redundancy judgment unit (redundancy judgment circuitry) 14, a redundancy avoidance unit (redundancy avoidance circuitry) 15, a second pattern generation unit (second pattern generator) 16, and a layout unit (layout circuitry) 17.

The logic synthesis unit 11 uses a logic synthesis tool to generate a design target circuit. The design target circuit is a semiconductor circuit for producing the semiconductor device 1 illustrated in FIG. 1.

The test circuit generation unit 12 divides the design target circuit into the plurality of circuit blocks 2 and incorporates the scan chain circuit 4 for a scan test into each of the circuit blocks 2. More specifically, the test circuit generation unit 12 cascades the plurality of flip-flops 7 in the circuit blocks 2 to produce the scan chain circuits 4 at the time of a scan test.

The first pattern generation unit 13 generates the first test pattern for a scan test. The first test pattern is input into each of the circuit blocks 2 to conduct a scan test using the scan chain circuit 4.

The redundancy judgment unit 14 provides the first test pattern to the circuit blocks 2 to conduct a scan test, and judges whether the scan test is redundant based on the results of the scan test. In this case, for example, if the failure detection rate is already saturated at the start of the scan test, the redundancy judgment unit 14 judges that the subsequent scan tests would be redundant as described later.

The redundancy avoidance unit 15 generates the clock gating circuit 3 that stops the supply of the clock signal Scan_Clk to the scan chain circuit 4 in the circuit block 2 judged as redundant. The redundancy avoidance unit 15 also generates in the circuit block 2 including the scan chain circuit 4 judged as redundant, the bypass path 5 that bypasses the scan chain circuit 4 judged as redundant and the selection circuit 6 that switches the selection between the output signal from the scan chain circuit 4 and the signal passing through the bypass path 5 based on the enable signal Scan_Enb.

The second pattern generation unit 16 generates a second test pattern for a scan test to be provided to the circuit block 2 including the scan chain circuit 4 judged as redundant by the redundancy judgment unit 14. The second test pattern with the omission of the test on the scan chain circuit 4 is shorter than the first test pattern.

The layout unit 17 designs the layout of the design target circuit based on the results of processing by the logic synthesis unit 11, the test circuit generation unit 12, and the redundancy avoidance unit 15.

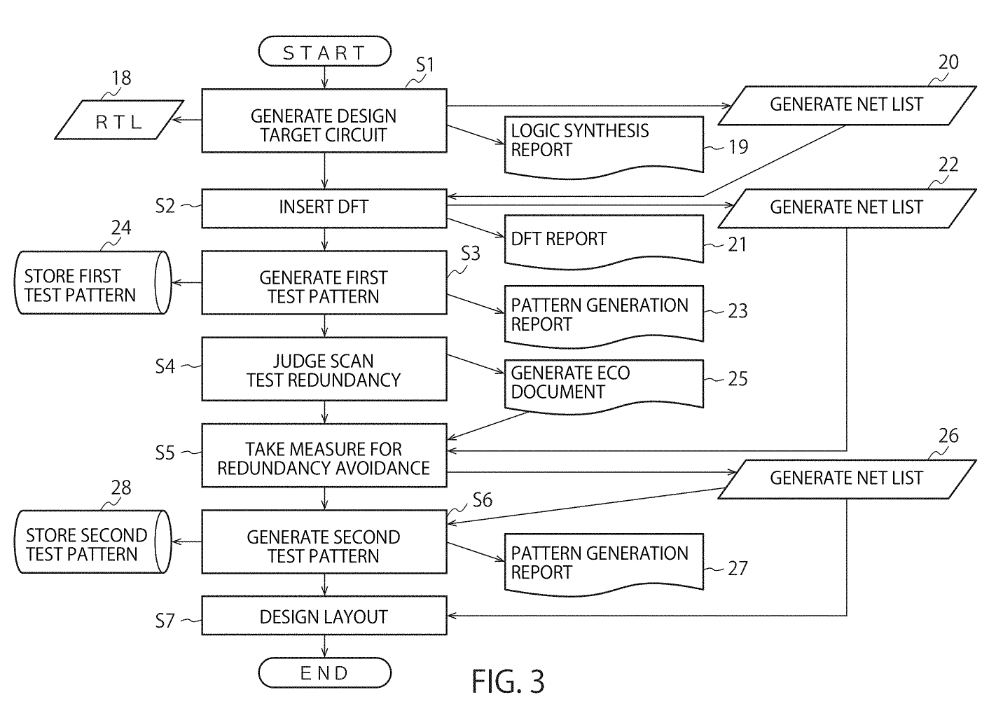

FIG. 3 is a flowchart of processing operations by the semiconductor designing device 10 illustrated in FIG. 2. The design target circuit can be described in Register Transfer Language (RTL), for example. The logic synthesis unit 11 inputs an RTL 18 describing the design target circuit into the logic synthesis tool to conduct logic synthesis and generate the design target circuit (step S1). At this time, a logic synthesis report 19 is generated. In addition, a net list 20 is generated based on the design target circuit generated in step S1.

Next, the test circuit generation unit 12 incorporates the scan chain circuits 4 into the design target circuit (step S2). The operation in step S2 is also called insertion of a Design For Test (DFT). By performing step S2, a DFT report 21 is generated. In addition, when the scan chain circuits 4 are incorporated into the design target circuit, the net list 22 is generated again.

Next, the first pattern generation unit 13 generates the first test pattern for a scan test (step S3). By performing step S3, a pattern generation report 23 is generated. In addition, the generated first test pattern is stored in a first test pattern storage unit 24.

Next, the redundancy judgment unit 14 provides the first test pattern to the circuit blocks 2 to conduct a scan test, and judges whether the scan test is redundant based on the results of the scan test (step S4). When the scan test is judged as redundant, an Engineering Change Order (ECO) document 25 is generated.

Next, the redundancy avoidance unit 15 takes a measure for avoidance of redundancy based on the net list 22 generated in step S2 and the ECO document 25 generated in step S4 (step S5). More specifically, in step S5, as illustrated in FIG. 1, the redundancy avoidance unit 15 generates the clock gating circuit 3 that stops the supply of the clock signal Scan_Clk to the scan chain circuit 4 in the circuit block 2 judged as redundant. The redundancy avoidance unit 15 also generates in the circuit block 2 including the scan chain circuit 4 judged as redundant, the bypass path 5 that bypasses the scan chain circuit 4 judged as redundant and the selection circuit 6 that switches the selection between the output signal from the scan chain circuit 4 and the signal passing through the bypass path 5 based on the enable signal Scan_Enb. After the generation of these circuits, the net list 26 is generated again.

Next, the second pattern generation unit 16 generates the second test pattern for a scan test to be provided to the circuit block 2 judged as redundant by the redundancy judgment unit 14 (step S6). By performing step S6, a pattern generation report 27 is generated. The generated second test pattern is stored in a second test pattern storage unit (second test pattern memory) 28.

Next, the layout unit 17 designs the layout of the design target circuit based on the results of processing by the logic synthesis unit 11, the test circuit generation unit 12, and the redundancy avoidance unit 15 (step S7).

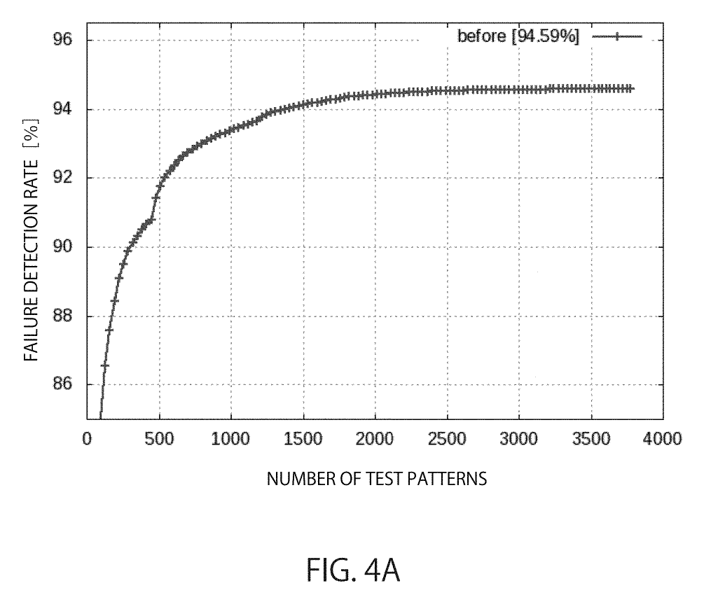

FIG. 4A is a diagram illustrating correspondences between the number of test patterns and failure detection rate. As illustrated in FIG. 4A, the failure detection rate becomes higher with increase in the number of test patterns. For example, the failure detection rate tends to be saturated when the number of the test patterns exceeds 1000, and the failure detection rate becomes fully saturated when the number of the test patterns exceeds 3500. It can be seen from the results in FIG. 4A that the failure detection rate hardly increases when the number of the test patterns exceeds 1000. This means that the test is redundant when the number of the test patterns exceeds 1000.

FIG. 4B is a diagram illustrating correspondences between the circuit blocks 2 and failure detection rate. Each of the plots in FIG. 4B indicates the failure detection rate with 1000 test patterns. The tips of the bar graphs in FIG. 4B indicate the failure detection rates in the saturated state. As illustrated in FIG. 4B, the failure detection rate varies between the circuit blocks 2 even when the number of the test patterns is the same. When the number of the test pattern is 1000, the failure detection rate reach the saturated state in some of the circuit blocks 2 but does not yet reach the saturated state in the other.

In step S4 of FIG. 3, the results illustrated in FIGS. 4A and 4B are acquired by simulation for the design target circuit. Then, the circuit blocks 2 having already become saturated are extracted based on the acquired results, the extracted blocks are judged as redundant, and the bypass path 5 and the selection circuit 6 are provided in each of the circuit blocks 2. This makes it possible to decrease the circuit blocks 2 to be subjected to a scan test, reduce consumption current, and shortening the test time without deterioration in test quality.

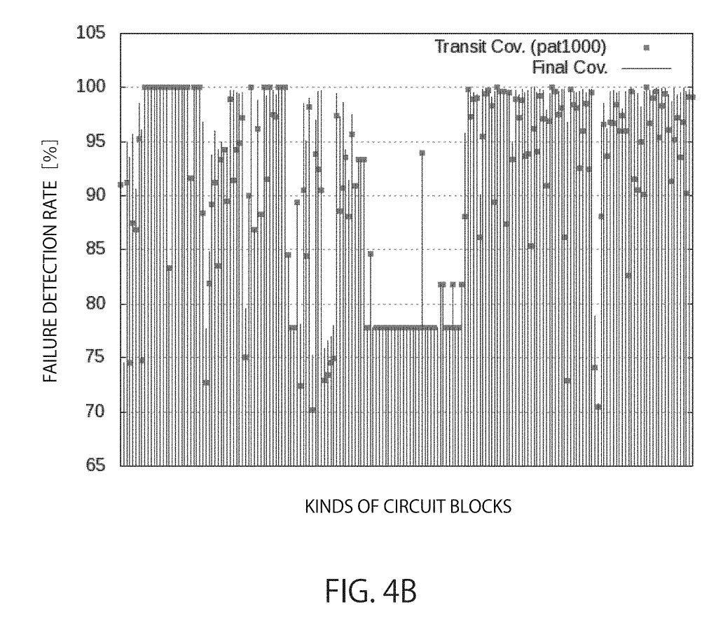

FIG. 5 is a block diagram illustrating a schematic configuration of a semiconductor test device 30 that conducts a scan test on the semiconductor device 1 illustrated in FIG. 1. The semiconductor test device 30 illustrated in FIG. 5 includes a failure detection rate monitoring unit (failure detection rate monitoring circuitry) 31, a saturation tendency determination unit (saturation tendency determination circuitry) 32, and a test pattern switching unit (test pattern switch) 33.

The failure detection rate monitoring unit 31 provides the first test pattern to the corresponding scan chain circuit 4 in each of the plurality of circuit blocks 2 to acquire the failure detection rate. The first test pattern is generated by the first pattern generation unit 13 in the semiconductor designing device 10 illustrated in FIG. 2.

The saturation tendency determination unit 32 determines whether the failure detection rate tends to be saturated. More specifically, the saturation tendency determination unit 32 acquires changes in the failure detection rate when the first test pattern is continuously provided to each of the circuit blocks 2 as illustrated in FIGS. 4A and 4B, for example.

For each of the circuit blocks 2 with the failure detection rate judged as saturated, the test pattern switching unit 33 stops the supply of the clock signal Scan_Clk to the scan chain circuit 4 by the clock gating circuit 3, inputs the corresponding second test pattern to the circuit block 2, and selects the bypass path 5 by the selection circuit 6 while switching between the logics of the enable signal Scan_Enb.

In this way, in the present embodiment, the scan chain circuits 4 are bypassed in the circuit blocks 2 for which it is estimated that the failure detection rate will not rise even with increase in the number of test patterns. This makes it possible to decrease the number of the circuit blocks 2 to be subjected to a scan test and reduce the consumption current at the time of a scan test. Reducing the consumption current at the time of a scan test suppresses a voltage drop, improves the test quality, and shortening the test time to decrease the cost for testing.

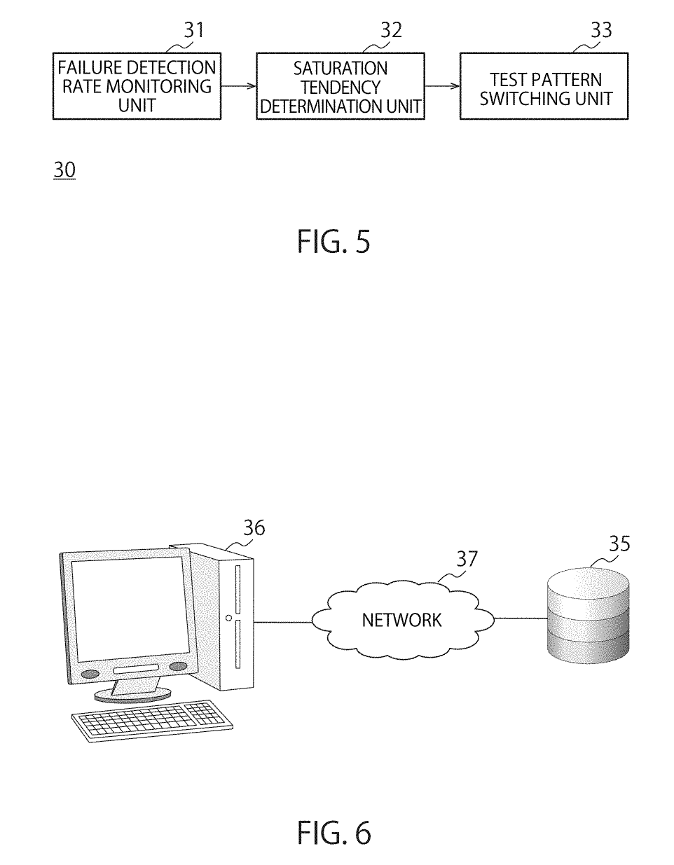

At least part of the semiconductor designing device 10 illustrated in FIG. 2 and the semiconductor test device 30 illustrated in FIG. 5 described above in relation to the embodiment may be formed from hardware or software. In the case of forming by software, as illustrated in FIG. 6, programs for implementing the functions of at least part of the semiconductor designing device 10 and the semiconductor test device 30 may be stored in a recording medium 35 such as a flexible disc or a CD-ROM and read and executed by a computer 36. The recording medium is not limited to a detachable one such as a magnetic disc or an optical disc but may be a fixed recording medium such as a hard disc device or a memory. The recording medium may be connected to a network 37.

In addition, the programs for implementing the functions of at least part of the semiconductor designing device 10 and the semiconductor test device 30 may be distributed via a network such as the internet (regardless of wireless or wired network). Further, the programs may be distributed via a wired line or a wireless line such as the internet or through a recording medium in an encrypted, modulated, or compressed state.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
one or more circuit blocks that comprises scan chain circuitry for a scan test; and
clock gating circuitry that switches supply and non-supply of a clock signal to the scan chain circuitry based on an enable signal, wherein
the one or more circuit blocks comprises:
a bypass path that bypasses the scan chain circuitry; and
selection circuitry that selects one of an output signal from the scan chain circuitry and a signal passing through the bypass path based on the enable signal.

2. The semiconductor device according to claim 1, wherein
the circuit blocks are connected to the clock gating circuitry, and
the clock gating circuitry switches supply and non-supply of the clock signal to the scan chain circuitry in the circuit blocks in synchronization with the enable signal.

3. The semiconductor device according to claim 1, wherein
the circuit blocks have a test pattern input terminal into which different test patterns are input depending on whether the enable signal is a first logic or a second logic.

4. The semiconductor device according to claim 1, wherein,
when the selection circuitry selects the signal passing through the bypass path, the clock gating circuitry stops supply of the clock signal to the scan chain circuitry.

5. The semiconductor device according to claim 1, wherein
the bypass path and the selection circuitry are provided in, among the plurality of circuit blocks each having the scan chain circuitry, the circuit block in which failure detection rate becomes saturated when the number of test patterns exceeds a predetermined number.

6. A semiconductor designing device comprising:
logic synthesis circuitry that generates a design target circuitry by logic synthesis;
test circuit generator that divides the design target circuitry into a plurality of circuit blocks and incorporates a scan chain circuitry for a scan test into each of the circuit blocks;
first pattern generator that generates a first test pattern for the scan test in each of the plurality of circuit blocks;
redundancy judgment circuitry that judges whether the scan test is redundant based on results of the scan test performed with the first test pattern provided to the corresponding circuit block;
redundancy avoidance circuitry that generates a clock gating circuitry to stop supply of a clock signal to the scan chain circuitry in the circuit block judged as redundant, and generates, in the circuit block including the scan chain circuitry judged as redundant, a bypass path to bypass the scan chain circuitry judged as redundant and a selection circuitry to switch between selection of an output signal from the scan chain circuitry and a signal passing through the bypass path based on an enable signal;
second pattern generator that generates a second test pattern for a scan test to be provided to the circuit block judged as redundant by the redundancy judgment circuitry; and
layout circuitry that designs layout of the design target circuitry based on results of processing by the logic synthesis circuitry, the test circuit generator, and the redundancy avoidance circuitry.

7. The semiconductor designing device according to claim 6, wherein
the redundancy judgment circuitry judges whether the scan test is redundant for each of the circuit blocks depending on whether failure detection rate becomes saturated when the number of test patterns exceeds a predetermined number.

8. A semiconductor test device for testing a semiconductor device designed by the semiconductor designing device according to claim 6, comprising:
failure detection rate monitoring circuitry that provides the first test pattern to the corresponding scan chain circuitry in at least one of the plurality of circuit blocks to acquire failure detection rate;
saturation tendency determination circuitry that determines whether the failure detection rate tends to be saturated; and
a test pattern switch that stops supply of a clock signal to the scan chain circuitry by the clock gating circuitry in the circuit block for which it is determined that the failure detection rate tends to be saturated, inputs the corresponding second test pattern into the circuit block, and selects the bypass path by the selection circuitry.

9. The semiconductor test device according to claim 8, wherein
when the enable signal is a first logic, the first test pattern is input into the circuit block and the selection circuitry selects an output signal from the scan chain circuitry, and
when the enable signal is a second logic, the second test pattern is input into the circuit block and the selection circuitry selects a signal passing through the bypass path.
